(19) United States
(12) Patent Application Publication
(10) Pub. No.: US 2003/0186532 A1
(43) Pub. Date: Oct. 2, 2003

(54) Method of forming a titanium-containing glue layer

(76) Inventors: Tung-Po Chen, Taichung City (TW); Alan K.L. Cheng, Kaohsiung City (TW); Tony Lin, Hsin-Chu City (JP); Ming-Yin Hao, Taipei City (JP)

Correspondence Address: Thomas T. Moga, Dickinson Wright PLLC, 1901 L Street NW, Suite 800, Washington, DC, 20036, US

(21) Appl. No.: 10/105,403

(22) Filed: Mar. 26, 2002

(51) Int. Cl. H01L 21/4763; H01L 21/44

(52) U.S. Cl. 438/629; 438/685; 438/637

(57) ABSTRACT

The present invention provides a method to form a titanium-containing glue layer and to reduce the diffusion of boron ion into a titanium-containing glue layer. The primary step is a nitrogen-ion implantation process in which the nitrogen ions are implanted into an interface region between a boron-ion doped region and a titanium-containing glue layer to form a nitrogen-ion-containing doped region. Afterward, a titanium-containing glue layer is conformally deposited on the surface of the nitrogen-ion-containing doped region by a TiCl₄-based CVD method. Because the temperature used in the CVD is so high that an ion diffusion occurs in the interface region between the nitrogen-ion-containing doped region and the titanium-containing glue layer, a titanium nitride layer is then formed in the interface region by a contact of the titanium ions and the nitrogen ions. The boron ions can not pass through the nitrogen-ion-containing doped region and the titanium nitride layer into the titanium-containing glue layer. Consequently, the present method can avoid those problems caused by TiB.

### BACKGROUND

1.Field of the Invention

The present invention generally relates to a method of forming a titanium-containing glue layer, and in particular to a method for reducing a diffusion of boron ions into the titanium-containing glue layer.

2. Description of the Prior Art

In recent years, the technique of the integral circuits is developed to a sub-0.18 μm process. As the feature size continues to decrease, the size of contact opening may also decrease, so that a contact opening with a high aspect ratio will be obtained.

In a formation of a plug, a titanium-containing glue layer is generally used for improving the adhesion of the plug to other material. A conventional method of forming a titanium-containing glue layer is the ionized metal plasma (IMP) method. But, as the feature size decreases, the contact opening also decreases. Hence, when a glue layer is formed by the conventional IMP method, the glue layer will easily stack on the edge of the top of the contact opening, so that an unfavorable void is then formed. The detail are described as following. Firstly, a substrate 10 is provided, as shown in FIG. 1. A PMOS transistor is previously formed on the substrate 10, and the PMOS transistor comprises a gate 20, a drain 30, a source 40, and a gate sidewall 50. Metal silicide layers, such as cobalt silicide layers, are used to improve conductivity, and the gate 20, the drain 30, and the source 40 have their own metal silicide layer (70,80,90) thereon. A dielectric layer 100 is formed on the PMOS transistor, and a contact opening is then formed in the dielectric layer 100 to expose a partial region of the drain 30. Then, a titanium-containing glue layer 110 is formed by IMP method to cover the surface of the dielectric layer 100 and the contact opening. As mentioned above, because a part of the glue layer 110 is stacked at the edge of the top of the contact opening, a void 120 is almost formed.

A recent method of forming a titanium-containing glue layer which can avoid said void is a TiCl₄-based CVD. As shown in FIG. 2, this method can conformally deposit a titanium-containing glue layer on the surface of the contact opening 210, so the method can avoid the formation of void. But, the temperature used in the CVD process is so high, about 550° C. [symbol] 800° C., that the boron ions in the PMOS transistor will diffuse into the glue layer and the ions are combined with the titanium ion to form a TiB layer 220. The TiB layer 220 will cause the trigger volt increase, the saturated resistance increase, and saturated current decrease, so that the performance of the PMOS transistor will degrade.

Therefore, the diffusion of boron ion into the glue layer should be avoided to improve the performance of the MOS transistor.

### SUMMARY

It is an object of the invention to provide a method for forming a titanium-containing glue layer.

It is another object of the invention to provide a method for reducing the diffusion of boron ions into a titanium-containing glue layer.

According to the foregoing objects, the present invention provides a method comprising the following steps: firstly, a structure is provided, and a p-type ion doped region is on the structure, such as the drain or the source of a PMOS transistor. A metal silicide layer, such as a cobalt silicide layer, is further formed on the p-type ion doped region to improve the conductivity. Then, a dielectric layer is formed to cover the p-type ion doped region. Afterward, a contact opening is formed in the dielectric layer to expose a partial region of the p-type ion doped region. Then, a nitrogen-ion implantation process is performed to implant the nitrogen ions into the partial region of the p-type ion doped region through the contact opening, so that a nitrogen-ion-containing doped region is formed. Afterward, by a TiCl₄-based chemical vapor deposition (CVD) process, a titanium-containing glue layer is conformally deposited on the surface of the dielectric layer, the contact opening, and the nitrogen-ion-containing doped region. Because of the high temperature used in the CVD process, an ion diffusion phenomenon occurs in the interface of the nitrogen-ion-containing doped region and the titanium-containing glue layer, so that a titanium nitride layer is formed by the contact of the titanium ions and the nitrogen ions. Furthermore, because of the existence of the nitrogen-ion-containing doped region and the titanium nitride layer, the boron ions can not pass through said nitrogen-ion-containing doped region and said titanium nitride layer. Consequently, the present method can avoid the problems caused by the TiB.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 shows a schematic cross-sectional diagram of a titanium-containing glue layer formed by a conventional IMP method;

FIG. 2 shows a schematic cross-sectional diagram of a titanium-containing glue layer formed by a conventional CVD method;

FIG. 3A to FIG. 3C show a series of schematic cross-sectional diagrams of a titanium-containing glue layer formed by the present method including a nitrogen-ion implantation and a CAD process;

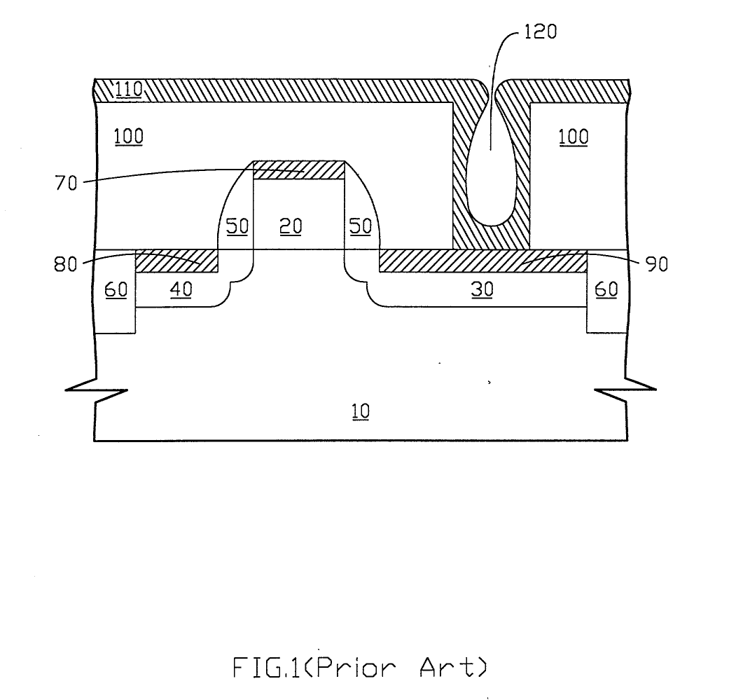

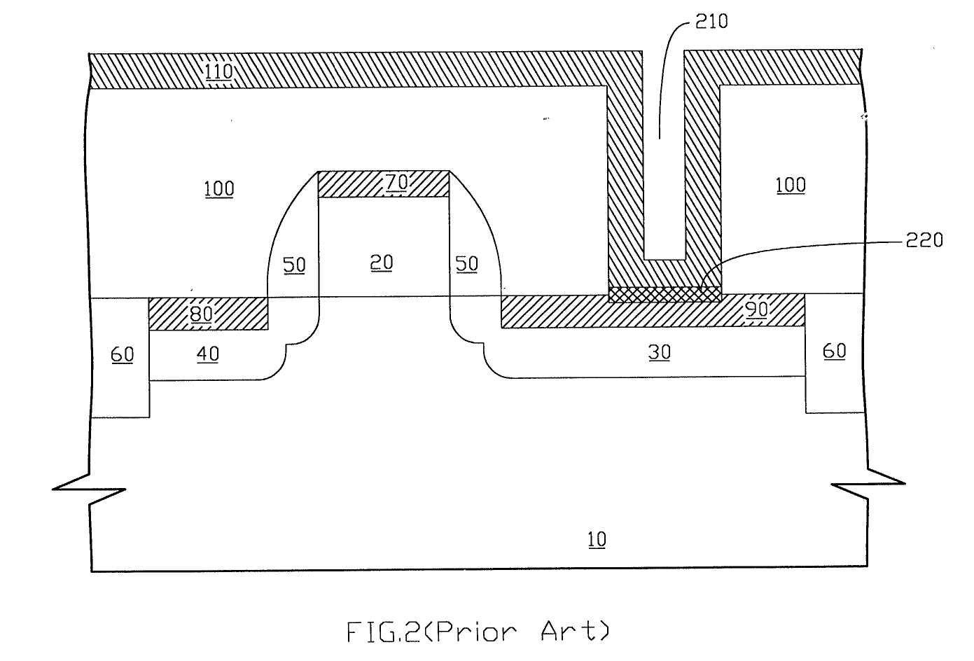

### DESCRIPTION OF THE PREFERRED EMBODIMENT

This invention provides a method for fabricating a titanium-containing glue layer. Said method comprises the steps thereinafter on a whole. A substrate with a first type ion doped region thereon is provided, and a metal silicide layer is formed on the first type ion doped region. Wherein said first type ion doped region may be a p-type ion doped region. By a ion implantation process, second type ions are implanted into the metal silicide layer, wherein said second type ions may be nitrogen-ions. Finally, the desired titanium-containing glue layer is fabricated onto the metal silicide layer.

Said p-type ion doped region may be a boron-ion doped region. One character of this invention is, the implantation region of said second type ion can efficiently prevent the above-mentioned phenomenon that the boron ions will diffuse into the glue layer and combine with the titanium ion to form a TiB layer. One preferred embodiment is described as follow.

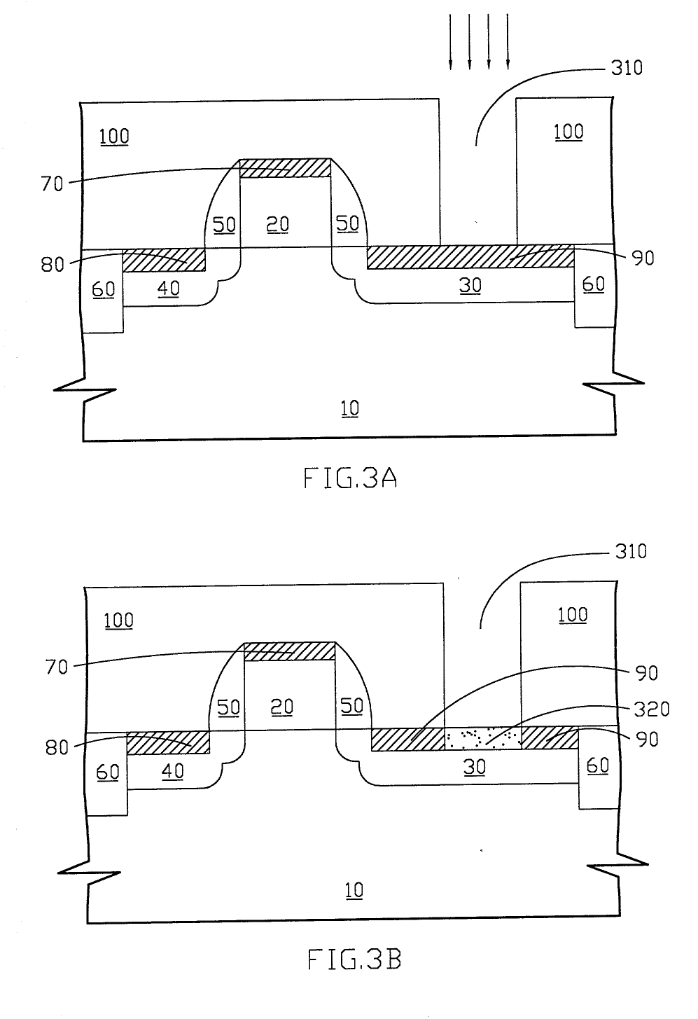

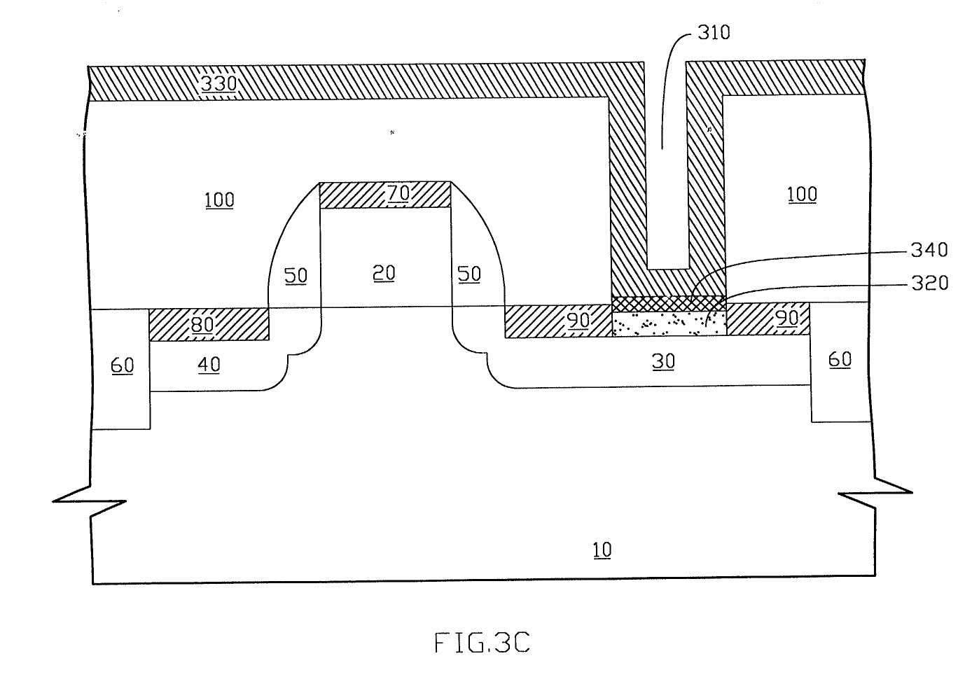

In this present invention, we provide a method to reduce the diffusion of boron-ion into a titanium-containing glue layer, and this method comprises the following steps: firstly, as shown in FIG. 3A, a substrate 10 is provided, and a PMOS transistor is formed on the substrate 10. The PMOS transistor comprises a gate 20, a drain 30, a source 40, and a sidewall 50. Metal silicide layers (70, 80, 90), such as cobalt silicide layers, are formed on the gate 20, the drain 30, and the source 40, respectively. These layers are used to improve the conductivity. PMOS transistors are separated by field oxide regions 60. Then, a dielectric layer 100 is deposited to cover the PMOS transistor. Secondly, a contact opening 310 is formed in the dielectric layer 100 to expose a partial region of the metal silicide layer 90 which is on the drain 30. Afterward, by a nitrogen-ion implantation process, nitrogen-ions are implanted into the partial region of the metal silicide layer 90 through the contact opening 310 to form a nitrogen-ion-containing metal silicide region 320, as shown in FIG. 3B. Then, by a TiCl₄-based chemical vapor deposition (CVD) process, a titanium-containing glue layer 330 is conformally deposited on the surface of the dielectric layer 100, contact opening 310, and the nitrogen-ion-containing metal silicide region 320, as shown in FIG. 3C. Because of the high temperature used in the CVD process, an ion diffusion phenomenon occurs in an interface between the nitrogen-ion-containing metal silicide region 320 and the titanium-containing glue layer 330, so that a titanium nitride (TiN) layer 340, as shown in FIG. 3C, is formed by a contact of titanium ions and nitrogen ions.

Because of the existence of the nitrogen-ion-containing metal silicide region 320 and the TiN layer 340, the boron ions in the PMOS transistor cannot pass through said metal silicide region 320 and said TiN layer 340 to diffuse to the titanium-containing glue layer 330. Consequently, the present method can avoid the problem caused by the TiB which is formed by a combination of titanium ions and boron ions. In addition, a metal plug will be formed in the contact opening for the following interconnect process.

It should be noted that the CVD process used to form a glue layer can be substituted by any other process which can do the same. Besides, although the nitrogen-ions are implanted into a metal silicide layer, it don't mean that the metal silicide layer is necessary. In other words, a nitrogen-ion implantation is exactly necessary for an interface region between a boron-ion doped region and a titanium-containing glue layer.

Although specific embodiments have been illustrated and described, it will be obvious to those skilled in the art that various modifications may be made without departing from what is intended to be limited solely by the appended claims.

What is claimed is:

1. A method for forming a titanium-containing glue layer, said method comprising the steps of:
providing a structure, said structure comprises a substrate, a p-type ion doped region on said substrate, and a metal silicide layer on said p-type ion doped region;
forming a dielectric layer on said structure to cover said substrate, said p-type ion doped region, and said metal silicide layer;
forming a contact opening in said dielectric layer to expose a partial region of said metal silicide layer;
performing an ion implantation to implant plurality of ions into said partial region of said metal silicide layer through said contact opening;
conformally forming a titanium-containing glue layer on the surface of said dielectric layer and said partial region of said metal silicide layer.

2. The method according to claim 1, said method further comprising a step of forming a contact plug by depositing a metal layer to fill up said contact opening.

3. The method according to claim 1, wherein said p-type ion doped region is a boron-ion doped region.

4. The method according to claim 1, wherein said metal silicide layer is a cobalt silicide layer.

5. The method according to claim 1, wherein the plurality of ions in the ion implantation step are nitrogen ions.

6. The method according to claim 1, wherein said titanium-containing glue layer is formed by a chemical vapor deposition process.

7. The method according to claim 6, wherein said chemical vapor deposition process is performed at a temperature range about 550° C. to about 800° C.

8. A method for forming a titanium-containing glue layer on a PMOS transistor, said method comprising the steps of:
providing a structure, said structure comprises a substrate, a PMOS transistor with a p-type ion doped region on said substrate, and a metal silicide layer on said p-type ion doped region;
forming a dielectric layer on said structure to cover said substrate and said PMOS transistor;
forming a contact opening in said dielectric layer to expose a partial region of said metal silicide layer;
performing an ion implantation to implant nitrogen ions into said partial region of said metal silicide layer through said contact opening;
conformally forming a titanium-containing glue layer on the surface of said dielectric layer and said partial region of said metal silicide layer.

9. The method according to claim 8, said method further comprising a step of forming a contact plug by depositing a metal layer to fill up said contact opening.

10. The method according to claim 8, wherein said p-type ion doped region is a drain.

11. The method according to claim 8, wherein said p-type ion doped region is a source.

12. The method according to claim 8, wherein said p-type ion doped region is a boron-ion doped region.

13. The method according to claim 8, wherein said metal silicide layer is a cobalt silicide layer.

14. The method according to claim 8, wherein said titanium-containing glue layer is formed by a chemical vapor deposition process.

15. The method according to claim 14, wherein said chemical vapor deposition process is performed at a temperature range about 550° C. to about 800° C.

16. A method for forming a titanium-containing glue layer, said method comprising the steps of:
providing a substrate, said substrate comprises a first type ion doped region on said substrate, and a metal silicide layer on said first type ion doped region;
performing an ion implantation to implant a second type ion into said metal silicide layer; and
conformally forming a titanium-containing glue layer on the surface of said metal silicide layer.

17. The method according to claim 16, wherein said first type ion doped region is a p-type ion doped region.

18. The method according to claim 16, said method further comprising a step of forming a contact plug by depositing a metal layer to fill up said contact opening.

19. The method according to claim 17, wherein said p-type ion doped region is a boron-ion doped region.

20. The method according to claim 16, wherein said metal suicide layer is a cobalt silicide layer.

21. The method according to claim 16, wherein the plurality of ions in the ion implantation step are nitrogen ions.

22. The method according to claim 16, wherein said titanium-containing glue layer is formed by a chemical vapor deposition process.

23. The method according to claim 22, wherein said chemical vapor deposition process is performed at a temperature range about 550° C. to about 800° C.
